(19) United States
(12) Patent Application Publication
(10) Pub. No.: US 2026/0086575 A1
(43) Pub. Date: Mar. 26, 2026

(54) AI Drone and Wireless charging tower System for Anomaly Detection

(71) Applicant: Gustavo Adolfo Velasquezfernandez, bellport, NY (US)

(72) Inventor: Gustavo Adolfo Velasquezfernandez, bellport, NY (US)

(21) Appl. No.: 18/892,421

(22) Filed: Sep. 22, 2024

(51) Int. Cl. G05D 1/689; B64U 80/25; G01R 31/58; G05D 1/661; G05D 105/85; G05D 109/25; H02J 7/35; H02J 50/10

(52) U.S. Cl. CPC G05D 1/689; B64U 80/25; G05D 1/661; H02J 7/35; H02J 50/10; G01R 31/58; G05D 2105/85; G05D 2109/254

(57) ABSTRACT

A system designed to continuously and autonomously monitor power lines using AI Drones and Wireless Charging Towers. The Wireless Charging Towers are powered by solar panels, which provide energy to wireless charging pads that recharge the AI Drones. These AI Drones are equipped with sensors to detect heat anomalies, such as sparks from power lines caused by faulty equipment or trees falling onto the lines. Sparks left undetected can lead to wildfires. The drones patrol between the towers, placed along the power lines, and this system may allow early detection of sparks before they escalate into fires. By identifying these hazards quickly, the system may significantly reduce the number of wildfires caused by power line failures.

The present invention relates to an autonomous AI Drone aerial system for monitoring and alerting upon detection of anomalies in multiple environments. More particularly, the present invention is a system for the early detection of heat anomalies

### FIELD OF THE INVENTION

The present invention relates to an autonomous AI Drone aerial monitoring and detection system. This invention particularly relates to a system for continuous and autonomous monitoring for the early detection of heat anomalies.

### BACKGROUND OF THE INVENTION

Wildfires have always played a role in the natural lifecycle of forests, often clearing underbrush and rejuvenating ecosystems. In the past, natural causes like lightning strikes were the main source of wildfires, but recent years have seen a rise in fires due to human activity and failing infrastructure. Power lines in particular have become a significant source of ignition, especially in areas like California, where dry conditions and high winds can turn a minor spark into a devastating fire.

Power lines that stretch through wooded or remote areas are prone to being impacted by falling trees or branches, which can result in sparks that ignite dry vegetation below. These sparks often go unnoticed until the fire has grown out of control. While technology such as fault indicators and wireless sensors can detect electrical faults in power lines, they miss the crucial moment when a physical event, like a tree falling onto the line, occurs. This lack of detection has contributed to some of the most devastating wildfires in recent history.

One such fire is the Camp Fire of 2018, which began when a power line failed, sparking a blaze that became the deadliest wildfire in California's history. Despite the presence of modern detection systems, there was no immediate alert when the physical failure occurred, allowing the fire to grow unchecked. Other recent wildfires, such as the Dixie Fire and the Kincade Fire, both of which were also caused by power lines, have been equally catastrophic, matching or exceeding the devastation of the Camp Fire. These fires highlight a recurring issue: physical events, not just electrical faults, are leading to major wildfires, and current systems are unable to respond in time.

As fire seasons grow longer and more intense, the risks associated with power line failures continue to increase. Prolonged dry conditions, rising temperatures, and strong winds create an environment where fires spread rapidly once ignited. While the majority of wildfires are caused by human activity, power lines remain a significant factor in these events, particularly when sparks from fallen lines go undetected for hours or even days. The systems currently in place do not have the capability to address these physical threats, leaving power companies and emergency responders without the tools they need to prevent small sparks from turning into largescale wildfires.

Traditional methods of monitoring power lines, such as routine inspections and occasional aerial surveys, are not sufficient to address this growing problem. These methods lack the ability to provide detection of physical threats, such as fallen trees or debris impacting the lines. As fire seasons continue to worsen, the need for a continuous, autonomous monitoring system that can detect both electrical and physical threats becomes increasingly critical.

What is needed is an autonomous aerial monitoring system capable of continuously detecting both electrical faults and physical impacts to power lines in real time. Such a system may immediately notify authorities when sparks or fallen trees are detected, allowing them to respond before the situation escalates into a wildfire. Operating 24/7, particularly in remote or difficult to reach areas, this system may provide a proactive approach to preventing wildfires, ensuring that small sparks are identified and managed before they turn into large, uncontrollable fires.

### BRIEF SUMMARY OF THE INVENTION

The present invention may have the ability to continuously and autonomously monitor power lines, providing early detection of heat anomalies such as sparking and/or sparks from power lines. The system may detect sparks from damaged power lines using the AI drones equipped with sensors to identify heat signatures and anomalies. the AI drone may alert and notify a user, control center, and/or fire department, of a detected anomaly/potential anomaly. The AI drone may be wirelessly charged through the wireless charging pad within the tower, which is powered by the solar panel and/or direct connection to a powerline. The placement of the wireless charging towers may be determined by the maximum flight range of the AI drone on a single charge. For instance, if the AI drone may continuously fly up to 10 miles on a single charge, a wireless charging tower may be placed at the starting point, with another at the 5 or 7mile mark. This system may rapidly alert users, such as power companies, fire departments, and operators at a control center, and may help minimize and/or reduce the risk of wildfires triggered by malfunctioning or damaged power lines by identifying sparks early and responding quickly to prevent them from spreading.

### BRIEF DESCRIPTION OF THE DRAWINGS

FIG. 1: Represents/Depicts an overview of the AI Drone and Wireless Charging Tower System 777 for monitoring and anomaly detection. The figure illustrates the strategic placement of Wireless Charging Towers 77 and the flight path of the AI Drones 88 as they patrol and gather data.

FIG. 2: Represents/Depicts a Cross Sectional View of the Wireless Charging Tower 77 and AI Drone 88 system. This figure highlights the internal components of the tower, including the automated shutters, charging apparatus, and data collection modules, as well as the docking process for the AI Drones 88.

FIG. 3: Represents/Depicts Embodiments of the AI Drone and Wireless Charging Tower Systems 777, showing multiple configurations of the system across various terrains, showcasing how the towers are adapted to different environments such as remote areas, forests, or urban settings.

FIG. 4: Represents/Depicts the start of the AI Drone 88 monitoring cycle between towers. The figure shows the initial deployment phase of the AI Drone(s) 88 as they begin their programmed path between Wireless Charging Towers 77.

FIG. 5: Represents/Depicts a Flowchart of the Anomaly Detection Process for AI Drone(s) 88 along powerlines. This flowchart demonstrates the decision-making process of the drone's AI, detailing how anomalies such as damaged power lines or unauthorized access points are detected and reported.

FIG. 6: Represents/Depicts the AI Drone 88 One-Way Cycle Path Between Wireless Charging Towers 77. The figure outlines the pre-programmed path followed by the AI Drones 88 between towers, including recharge points and monitoring zones.

FIG. 7: Represents/Depicts another way of understanding the system's process, focusing on the interaction between the AI Drones 88, Wireless Charging Towers 77, and the central control unit where data is processed and analyzed for anomaly detection.

FIG. 8: Represents/Depicts the Surveillance and Monitoring of a Military Base or Prison Facility by AI Drone(s) 88. This figure shows how the system can be applied for high-security environments, with a focus on perimeter monitoring and quick anomaly response.

FIG. 9: Represents/Depicts a Flowchart of the Anomaly Detection Process by AI Drone(s) 88. The chart highlights the different stages of anomaly detection, from initial identification to verification, and how the AI Drone(s) 88 handle alerts and awaits further instructions from the control center.

FIG. 10: Represents/Depicts the Data Flow System for AI Drone(s) 88. This figure details the cloud-based system used to store and process data collected by the AI Drone(s) 88, emphasizing the integration of various data streams into the control center for real-time decision-making.

FIG. 11: Represents/Depicts the Comprehensive Data Network for AI Drone(s) 88 operations, showing how data from multiple drones and towers is collected, analyzed, and shared across the system, ensuring comprehensive coverage and monitoring.

FIG. 12: Represents/Depicts the Power Supply Process of the Wireless Charging Tower 77 for AI Drone(s) 88, illustrating the renewable energy sources used, such as solar panels, and the automated charging cycle of the AI Drones 88 when they dock.

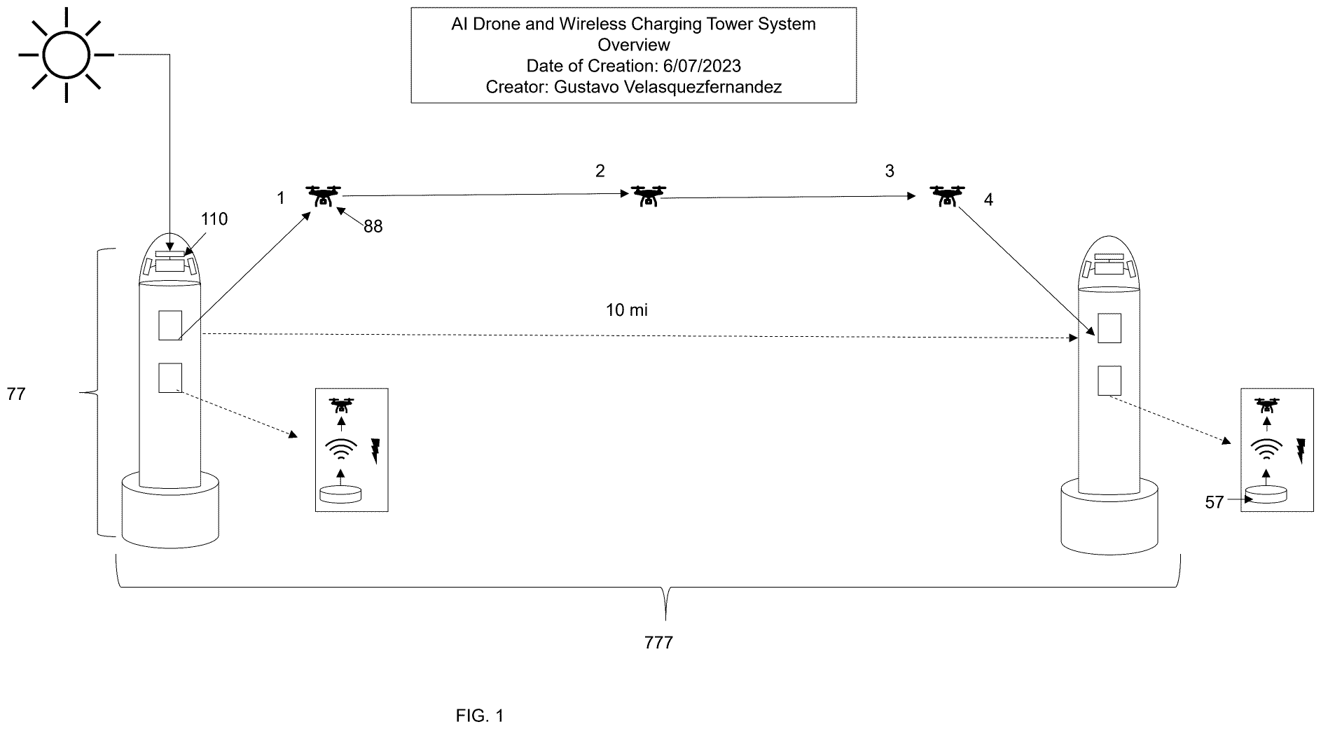

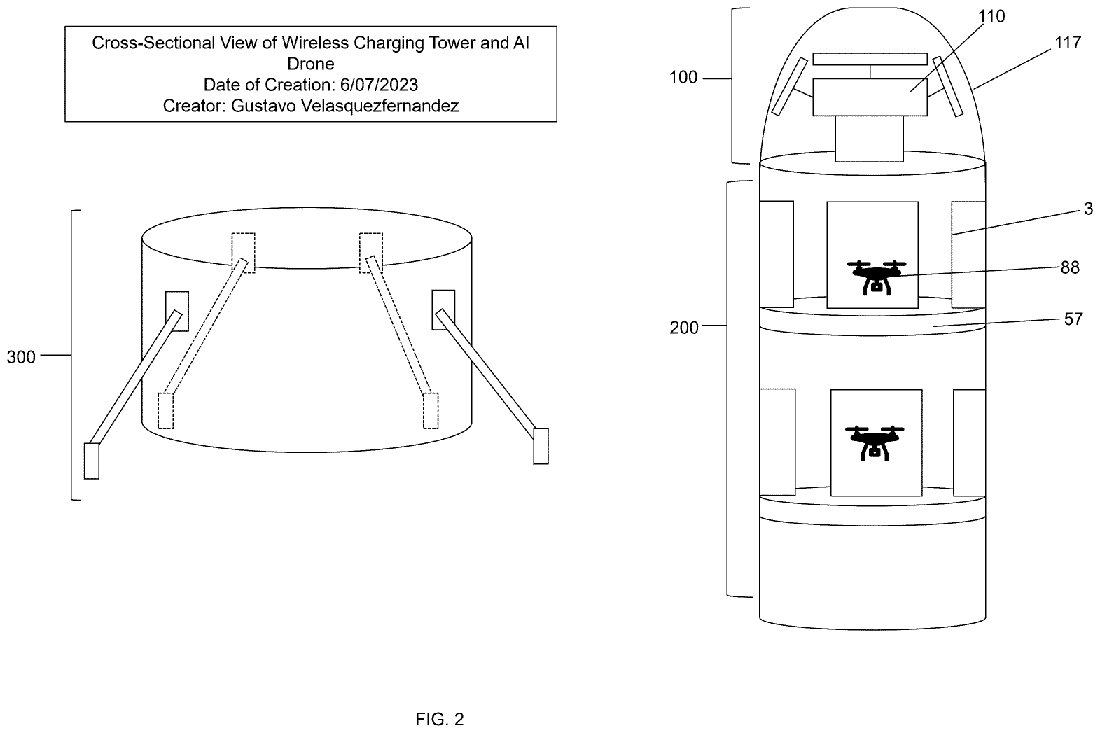

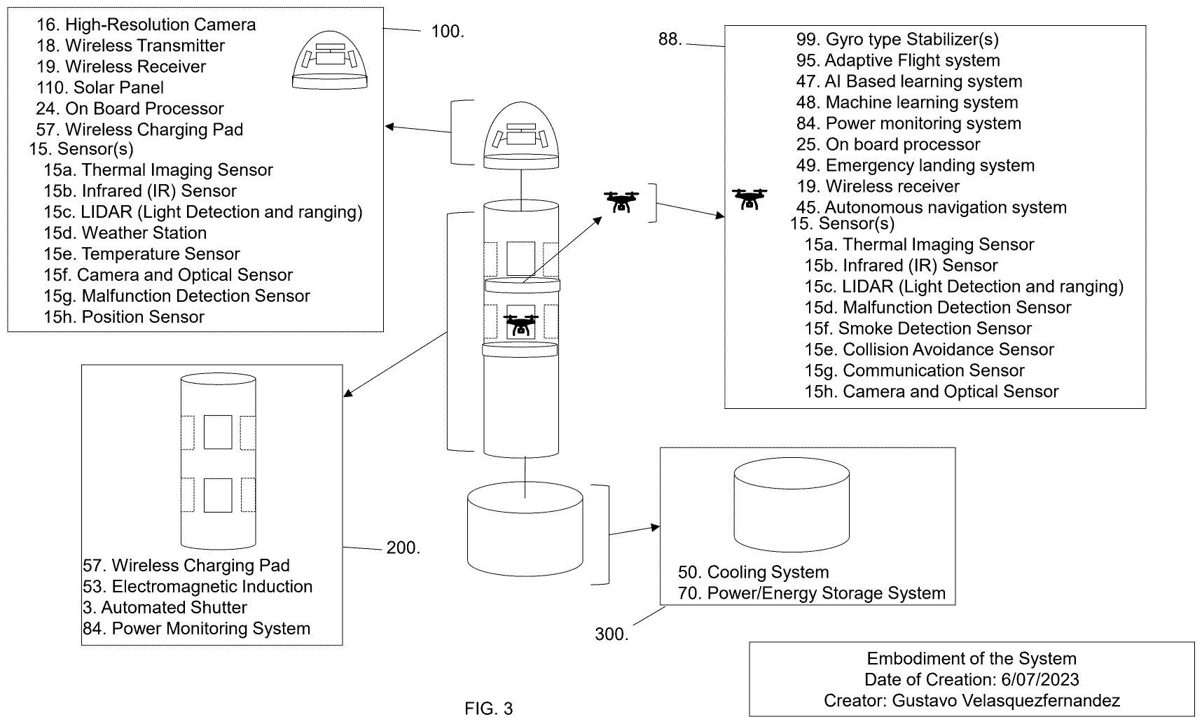

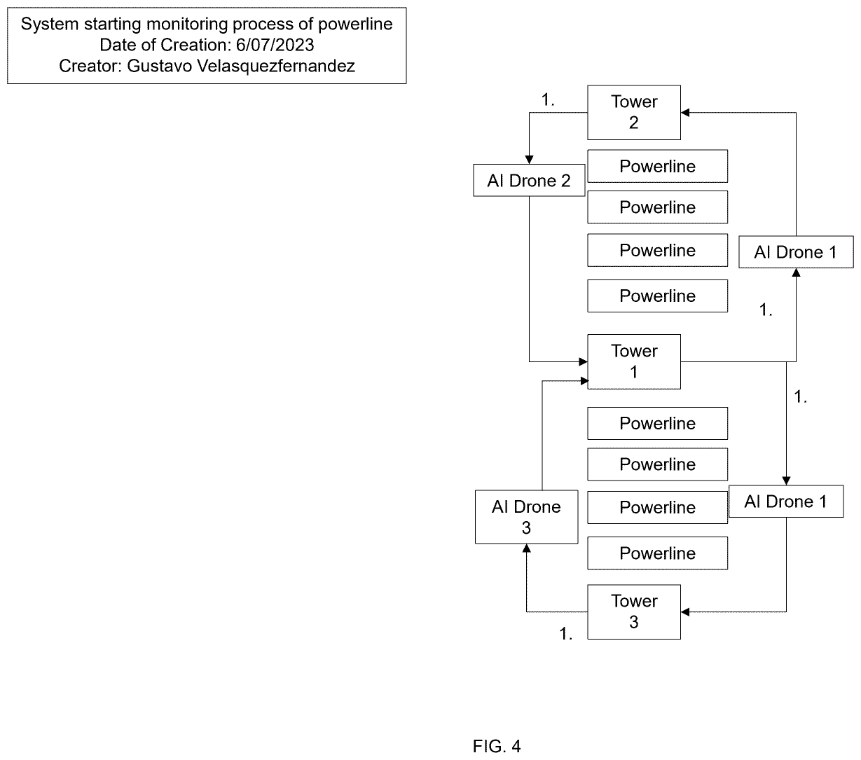

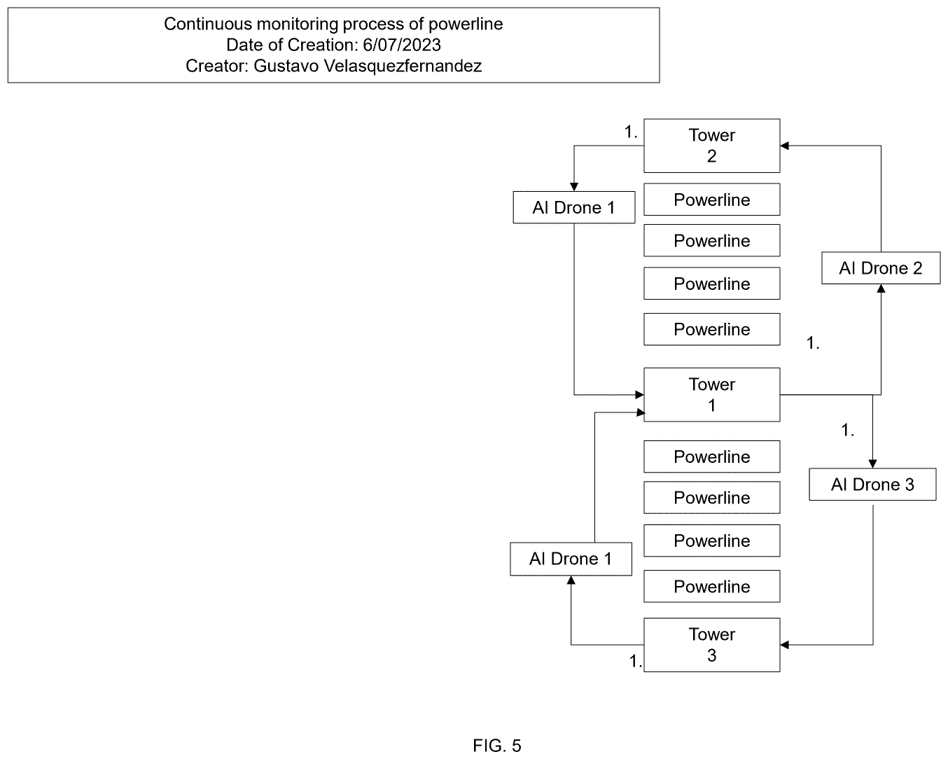

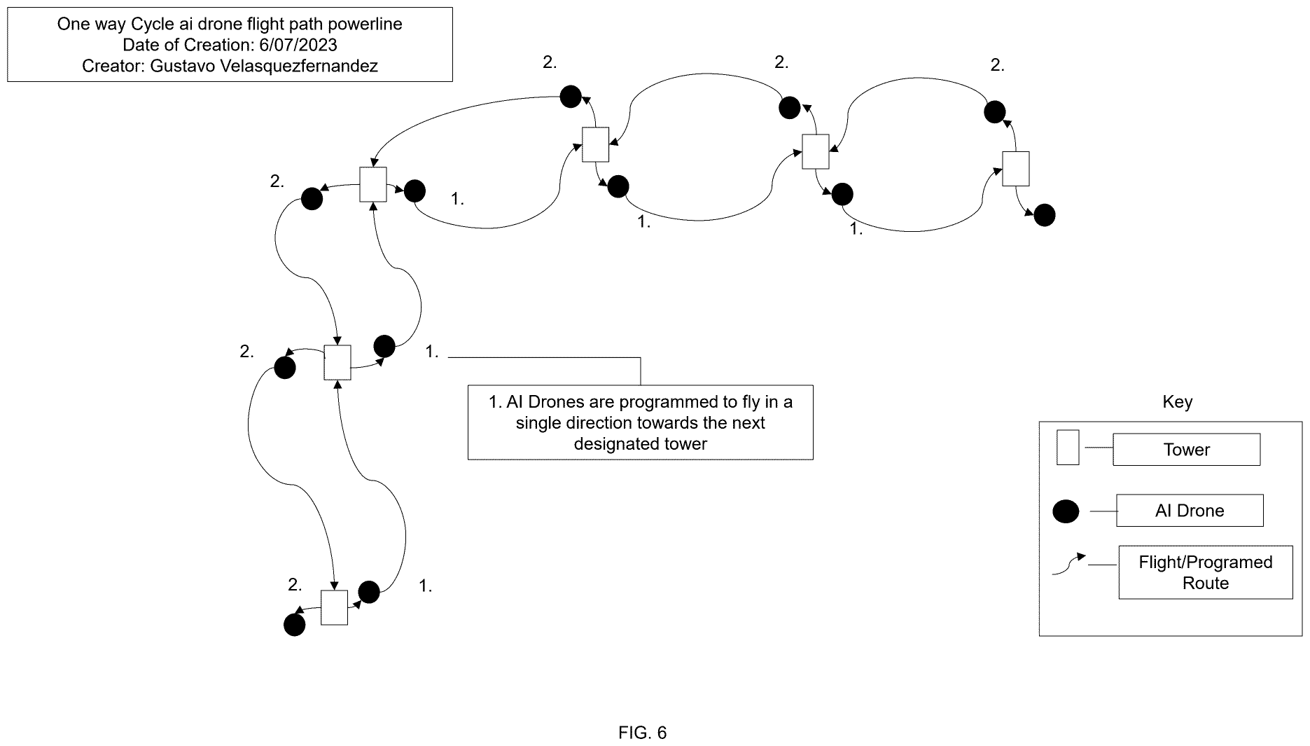

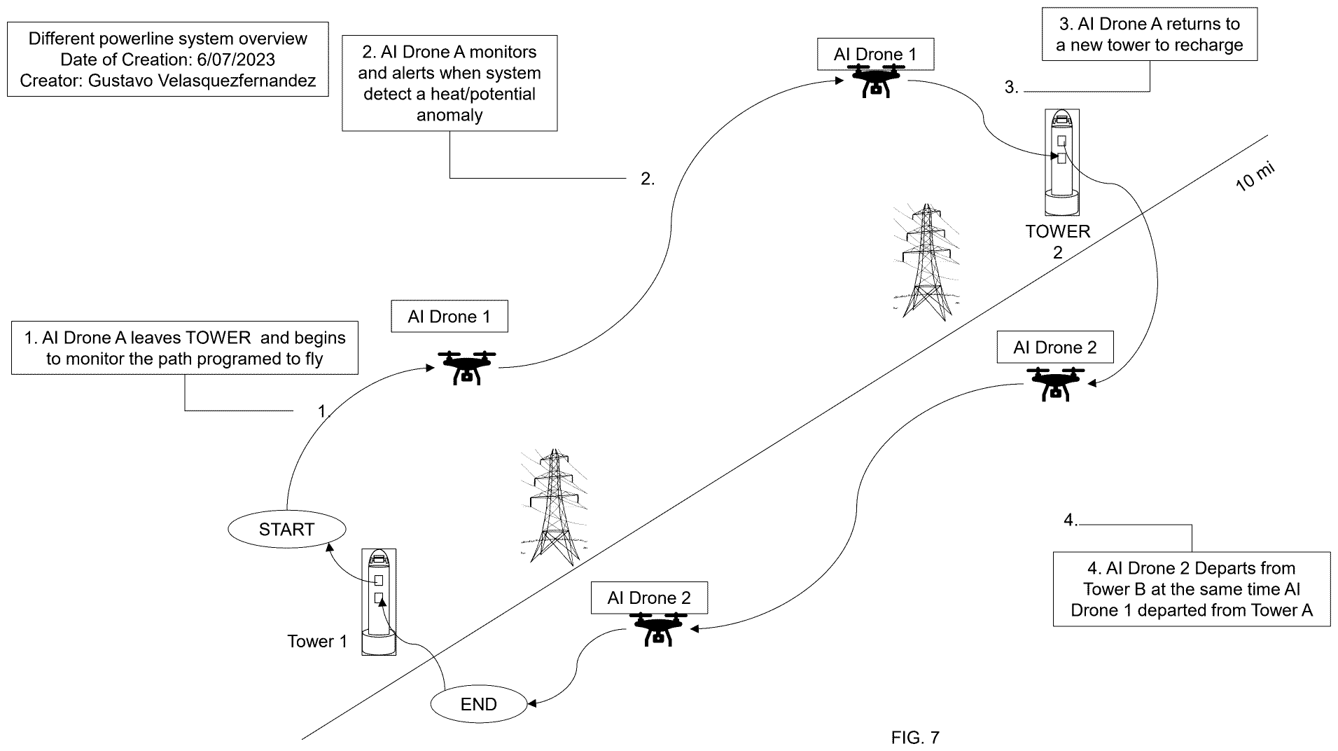

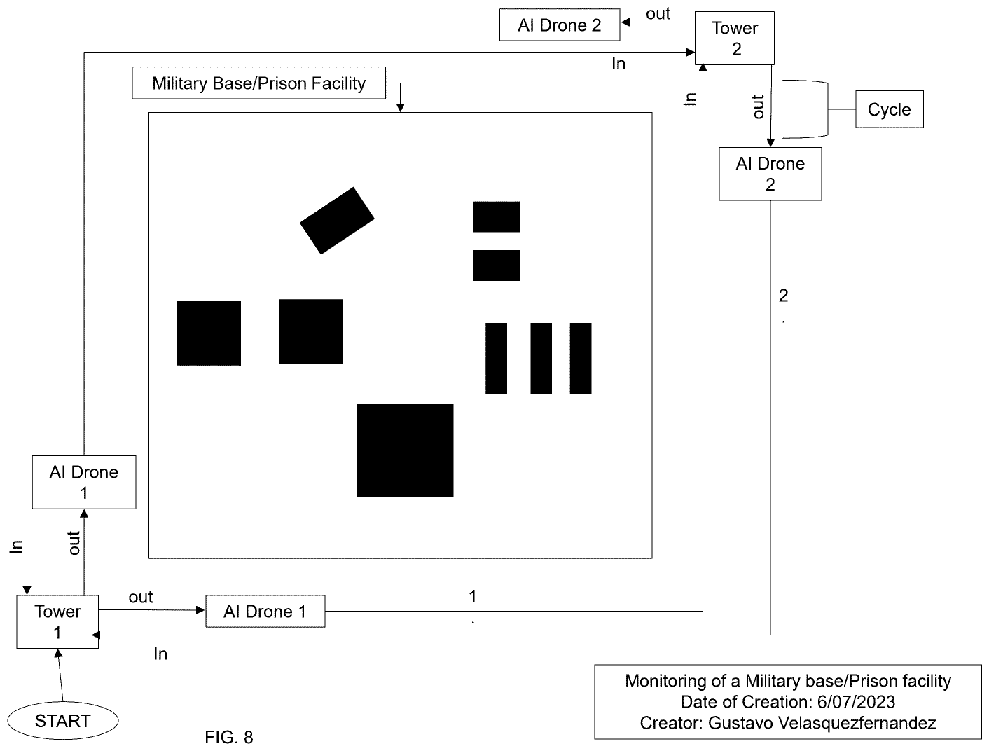

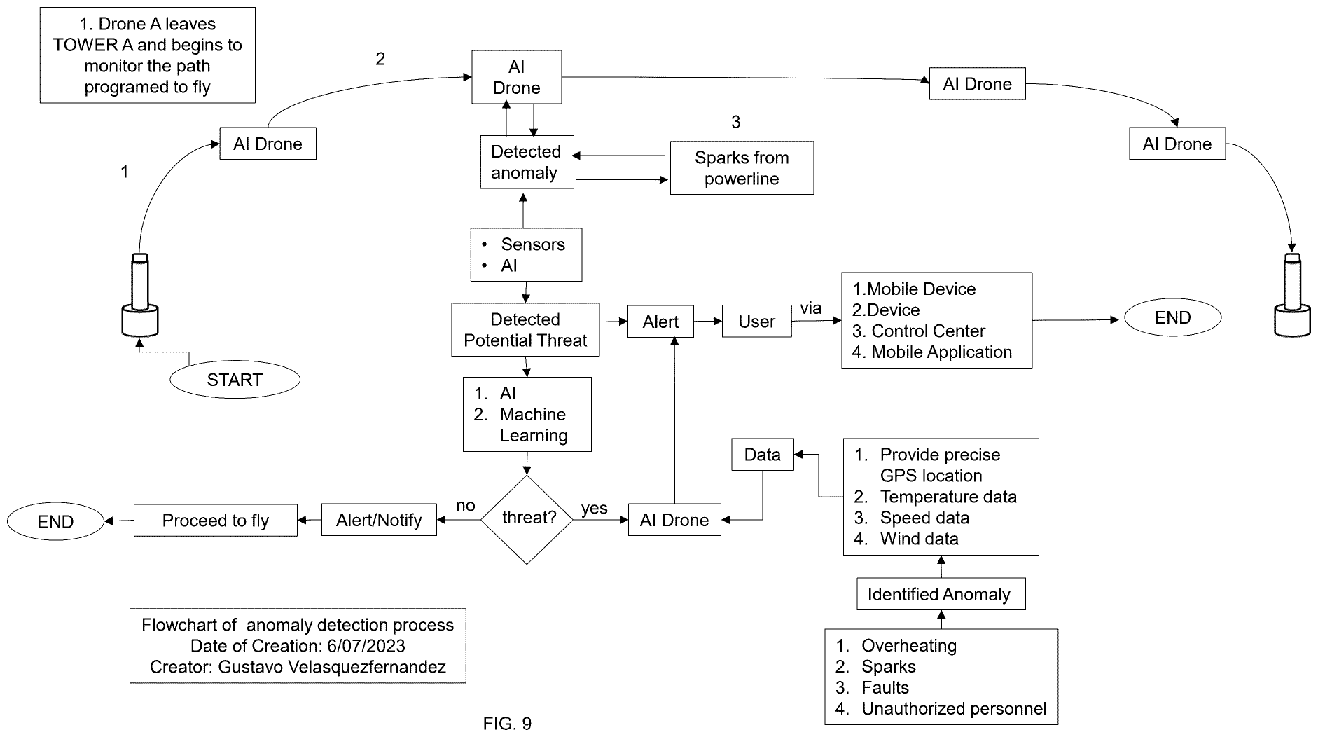

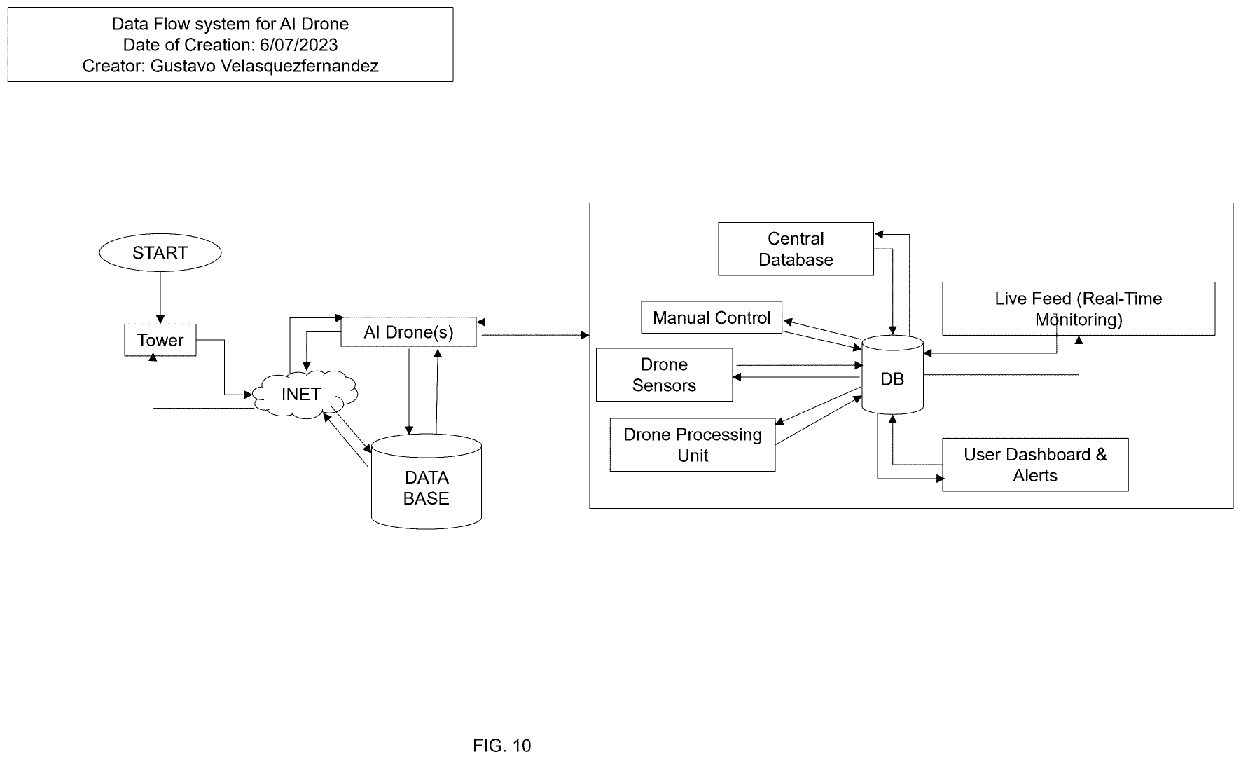

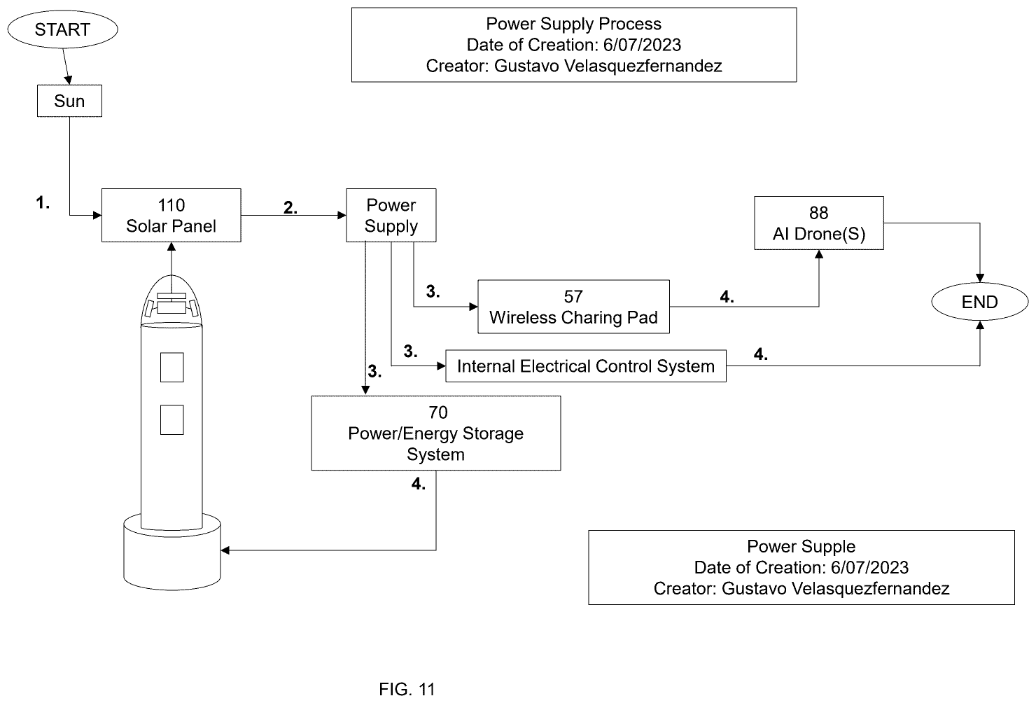

### SUMMARY OF THE INVENTION

The present invention relates to an autonomous AI drone aerial system for monitoring and early detection of anomalies in multiple environments. More particularly, the present invention is a system for the early detection of heat anomalies, providing alerts or notifications, and continuous, autonomous monitoring. The objective is to detect and take action to potential hazards, such as sparking power lines, to prevent damage and reduce the risk of wildfires.

### Early Detection

The AI Drone and Wireless charging tower System 777 may have the ability to detect heat anomalies, including but not limited to sparks, heat signatures, and other anomalies from damaged power lines, as well as it may detect trespassers and unauthorized individuals in remote areas using sensors 15 that may be in and/or on the ai drone(s) 88. This system 777 may operate continuously and autonomously, addressing a significant gap in current wildfire detection methods, particularly in regions where power lines extend across vast, hard to reach areas with limited monitoring capabilities.

Currently, there may be no effective system in place to rapidly detect when a tree falls onto a power line, causing damage and sparks, particularly in remote or geologically challenging locations. The difficulty in monitoring vast stretches of power lines means that sparks may occur and go unnoticed for hours or even days, potentially igniting a wildfire.

The AI Drone(s) 88 may be programmed to continuously and autonomously monitor the area around a single Wireless charging tower 77 or travel between multiple towers to cover larger areas. During their monitoring operations, the AI Drone(s) 88 may gather data and detect heat anomalies across these regions. Once the monitoring cycle is complete, the AI Drone(s) 88 may return to a designated Wireless charging tower 77, where the AI Drone(s) 88 are wirelessly charged by a wireless charging pad 57, that is being powered by using energy generated by the Solar Panel(s) 110. The system's ability to convert solar energy into power via the Solar Panel(s) 110 and store excess power in a Power Storage System ensures that it remains operational in diverse environments, providing long term, sustainable monitoring solutions.

The AI Drone(s) 88 may be equipped with sensors such as the Thermal Imaging Sensor 15a and Infrared (IR) Sensor 15b, allowing them to detect heat signatures and/or heat anomalies. When a potential or confirmed anomaly is detected, the AI Drone(s) 88 may have the ability to immediately notify a user or control center. This notification may provide live feed, accurate location data, direction, and the condition of the anomaly, enabling rapid assessment and intervention.

The AI Drone(s) 88 may also provide additional data, such as changes in the direction of a wildfire, which could further aid in response efforts. The data collected during the AI Drone(s) 88's flight cycles may be used to improve the system's detection capabilities over time, allowing the system to become more accurate with each deployment. Users and/or control center 31 may access this data through a mobile app, website, or dedicated control interface.

The objective of this system 777 is to ensure early detection of potential hazards, improve the monitoring of power lines, and reduce the risk of undetected fires from spreading uncontrollably. Over time, the system 777 may have the ability to save lives, protect properties, etc., by detecting heat anomalies and alerting a user/control center 31 as soon as the ai drone(s) 88 detects a heat anomaly.

### Brief Description of the Embodiments of the System

A detailed description of the hereinafter described embodiments of the disclosed apparatus and method are presented herein by way of explanation and not limitation with reference to the figures listed above. Although certain embodiments are shown and described in detail, various changes and modifications may be made without departing from the scope of the appended claims. The scope of the present disclosure will in no way be limited to the number of constituting components, the materials thereof, the shape thereof, the relative arrangement thereof, etc., and are disclosed simply as an example of embodiments of the present disclosure.

The embodiments of an AI Drone and Wireless charging tower System 777 may be comprised of a wireless charging tower(s) 77, an AI drone(s) 88, a sensor(s) 15, a power source 41, a solar panel(s) 110, a wireless transmitter 18, and a wireless charging pad(s) 57.

### Detail Description of the Embodiments of the System

Embodiments of the AI Drone and Wireless charging tower System 777 may be comprised of a wireless transmitter 18. The location of the wireless transmitter may be in the Wireless charging tower 77 and/or the AI Drone(s) 88. The wireless transmitter 18 may be any type of sensor, router, and/or device that may have the ability to provide internet to the AI Drone(s) 88 and the tower(s) 77. The purpose of using the wireless transmitter 18 is to provide internet to both the tower(s) 77 and the AI Drone(s) 88. The wireless transmitter 18 may have multiple functions, such as enabling communication between the AI Drone(s) 88, the tower(s) 77, and the user/control center 31 (via a mobile app, device, or control center 31). It may also allow users/control center 31 to view data, monitor live feeds, wirelessly control the AI Drone(s) 88, store data collected by the AI Drone(s) 88 in a cloud database, and provide accurate GPS locations of the Wireless charging tower 77 and the AI Drone(s) 88. Additionally, the wireless transmitter 18 may allow for alerts and/or notifications when an anomaly is detected.

The AI Drone and Wireless charging tower System 777 may comprise a power source 41. The power source 41 may be anything that may have the ability to provide energy or power to the system. The power source 41 may have the ability to convert sunlight into electricity or power, such as solar panels 110, and/or through direct connections to existing powerlines as the power source 41, or both. The power source 41 may further be comprised of one or more combinations of solar panels 110, rechargeable batteries, etc. For example, solar panels 110 may specifically be responsible for converting sunlight into power to charge or power the tower 77. A benefit of using solar panels 110 is that they provide a renewable, sustainable energy source, allowing the system to operate independently.

Embodiments of an AI Drone and Wireless charging tower System 777 may be comprised of an energy/power storage system 70. The energy storage system 70 may consist of one or more components such as battery storage, battery energy storage systems (BESS), residential photovoltaic (PV) systems, electric battery banks, or any other method capable of storing energy/power from a/the power source 41 such as sunlight that is being converted to power by the solar panel(s) 110. The energy storage system 70 stores excess energy generated by the solar panels 110 and/or power lines, which may then be used as a backup power source, allowing the system 777 to remain operational.

Embodiments of the AI Drone and Wireless charging tower System 777 may comprise a sensor(s) 15. A sensor(s) 15 may consist of one or more types of sensors, each with its own function. These sensors may operate independently or as part of a larger device, which may have the ability to use multiple sensors. For example, the system may use sensors that detect heat, such as a Thermal Imaging Sensor 15a or an Infrared (IR) Sensor 15b, along with other sensors capable of identifying heat related anomalies.

The system 777 may also be comprised of a Thermal Imaging Sensor 15a. The Thermal Imaging Sensor 15a may allow the AI Drone(s) 88 to have the ability to capture detailed thermal images, to detect various heat related anomalies. The Thermal Imaging Sensor 15a may allow the AI Drone(s) 88 to detect fallen trees that have damaged powerlines, identify sparks or fires caused by the impact, and spot unauthorized activities, such as trespassers via thermal reading. A benefit of the thermal imaging sensor 15a is that it may provide the system 777 and/or the ai drone(s) 88 to monitor and detect potential dangers more effectively.

The system 777 may also be comprised of an Infrared (IR) Sensor 15b. The Infrared (IR) Sensor 15b may have the ability to detect anomalies more effectively during nighttime operations. It may allow the AI Drone(s) 88 to identify heat sources and monitor temperature changes, particularly in low visibility conditions such as nighttime or heavy fog. The Infrared (IR) Sensor 15b may provide the ai drone(s) 88 the ability to detect potential hazards that are otherwise difficult to spot, such as hidden fires or overheating equipment. A benefit of the Infrared (IR) Sensor 15b is that it may allow the AI Drone(s) 88 to have the ability to detect fallen trees on powerlines at night, which helps prevent potential fire hazards from going unnoticed in dark and save lives.

The system 777 may also be comprised of a LIDAR (Light Detection and Ranging) Sensor 15c. The LIDAR Sensor 15c may measure light pulses and the time it takes for them to return after reflecting off surfaces. The LIDAR Sensor 15c may allow the AI Drone(s) 88 to generate detailed three dimensional maps of the surrounding environment, improving navigation through complex terrains and in obstacle avoidance. A benefit of the LIDAR Sensor 15c is that it may allow the AI Drone(s) 88 to have the ability to navigate with greater precision and safety during complex maneuvers, making it more capable in challenging environments.

The System 777 may also be comprised of a Malfunction Detection Sensor 15d. The Malfunction Detection Sensor 15d may be any type of device capable of detecting issues such as voltage fluctuations, physical vibrations, or other internal and external malfunctions within the system 777. The Malfunction Detection Sensor 15d may provide early detection of system failures, allowing for timely intervention to prevent any disruptions in monitoring or operation, especially in remote areas where manual checks may be infrequent.

The System 777 may also be comprised of a Collision Avoidance Sensor 15e. The Collision Avoidance Sensor 15e may be any type of device or system that may have the ability to detect obstacles in the flight path of the AI Drone(s) 88. The Collision Avoidance Sensor 15e may allow the AI Drone(s) 88 to adjust its flight path time to avoid collisions with objects such as aerial devices, buildings, or natural obstacles. A benefit of the Collision Avoidance Sensor 15e is that it may help the AI Drone(s) 88 reduce the risk of accidents, improve the safety of the AI Drone(s) 88 during flight, and improve the AI Drone(s) 88′s overall performance and reliability for future missions.

The System 777 may also be comprised of a Smoke Detection Sensor 15f. The Smoke Detection Sensor 15f may be any type of sensor capable of detecting the presence of smoke within the monitored area. The Smoke Detection Sensor 15f may allow the AI Drone(s) 88 to identify potential wildfires or hazardous events involving smoke.

The System 777 may also be comprised of a Communication Sensor 15g. The Communication Sensor 15g may be any type of system that supports wireless data transmission between the AI Drone(s) 88 and the Tower(s) 77. The Communication Sensor 15g may allow the AI Drone(s) 88 to transmit data such as video feeds and sensor readings. A benefit of the Communication Sensor 15g is that it may allow the AI Drone(s) 88 to maintain reliable and continuous communication, even in areas with weak signals or interference, which may be crucial for maintaining effective monitoring in remote or rugged environments.

The System 777 may also be comprised of a Camera and Optical Sensor 15h. The Camera and Optical Sensor 15h may be any type of sensor that provides high resolution, 360 degree visual coverage. The Camera and Optical Sensor 15h may allow the AI Drone(s) 88 to capture detailed visual data, improving its monitoring capabilities. A benefit of the Camera and Optical Sensor 15h is that it may allow the AI Drone(s) 88 to provide comprehensive visual insight, which, when combined with other sensors, may improve anomaly detection and response time.

Some sensors may be used in both devices. For example, the AI Drone(s) 88 and the Wireless charging tower 77 may both have a Malfunction Detection Sensor 15d, capable of detecting any malfunctions in the system.

### Detailed Description of the Embodiments of the AI Drone

Embodiments of an AI Drone and Wireless charging tower System 777 may further comprise AI Drone(s) 88. The AI Drone(s) 88 may vary in size, shape, and configuration, potentially featuring one or more wings or propellers, depending on the system's specific requirements. The AI Drone(s) 88 may be constructed using existing drones or by modifying existing drones so that they may operate within specific conditions. The AI Drone(s) 88 may be designed to withstand high winds, sun heat, and other challenging environmental conditions. The AI Drone(s) 88 may have the ability to be programmed to detect specific anomalies and alert a user and/or control center 31 about any detected anomaly. Additionally, the AI Drone(s) 88 may continuously monitor, and store data collected during each flight. This data may help improve the AI Drone(s) 88's ability to classify anomalies and increase the accuracy of anomaly detection. The AI Drone(s) 88 may also be programmed to know the location of other towers and the Wireless Charging Pad 57.

The AI Drone(s) 88 may be comprised of one or more and not limited to, the following components: a Gyro Type Stabilizer(s) 99, a Adaptive Flight Algorithms 95, a Anomaly Detection System 47, a Machine Learning Algorithm(s) system 97, an Onboard Processor 25, an Emergency Landing System 49, a Wireless Transmitter 18, a 5G LTE Module 46, a Autonomous Navigation System 45, a High Resolution Camera 16, and sensor(s) 15.

Embodiments of the AI Drone(s) 88 may further be comprised of Gyro Type Stabilizer(s) 99. The Gyro Type Stabilizer(s) 99 may be any device that helps maintain balance and control during flight, ensuring smooth and steady movement. The Gyro Type Stabilizer(s) 99 may have the ability to help the AI Drone(s) 88 constantly adjust its orientation and tilt, enabling navigation and reducing the impact of turbulence or sudden gusts. A benefit of Gyro Type Stabilizer(s) 99 may be that it may allow the AI Drone(s) 88 to remain stable during surveillance, monitoring, and data collection, even in unpredictable weather conditions. This stabilization may be particularly useful when flying over rugged terrain or during strong winds, where maintaining flight stability is critical for accurate data capture and performance.

Embodiments of the AI Drone(s) 88 may further be comprised of Adaptive Flight Algorithms 95. The Adaptive Flight Algorithms 95 may be any set of algorithms that continuously analyze data collected from onboard sensors to adjust the drone's speed, altitude, and trajectory. The Adaptive Flight Algorithms 95 may have the ability to help the AI Drone(s) 88 respond effectively to changing environmental conditions and flight challenges. A benefit of Adaptive Flight Algorithms 95 may be that they may ensure stable flight, even in unpredictable weather conditions such as strong winds or turbulence. These algorithms may allow the AI Drone(s) 88 to optimize its path and conserve energy during long flights, increasing its operational efficiency and extending its range of coverage.

Embodiments of the AI Drone(s) 88 may further be comprised of Anomaly Detection System 47. The Anomaly Detection System 47 may be any system that autonomously identifies irregularities or potential hazards in the environment by analyzing data from sensors like thermal imaging and infrared. The Anomaly Detection System 47 may have the ability to help the AI Drone(s) 88 detect anomalies such as sparks from powerlines, fallen trees, or unauthorized objects, and notify the control center. A benefit of Anomaly Detection System 47 may be that it may improve its accuracy over time through machine learning, making it more reliable in identifying true hazards. This capability may allow the system to learn from past incidents and adjust its detection criteria, helping reduce false positives and improving overall safety and efficiency in wildfire detection and prevention.

Embodiments of the AI Drone(s) 88 may further be comprised of Machine Learning Algorithm(s) system 97. The Machine Learning Algorithm(s) system 97 may be any set of algorithms that process information gathered by the drone's sensors to identify patterns and trends. The Machine Learning Algorithm(s) system 97 may have the ability to help the AI Drone(s) 88 learn from past experiences, refining its detection capabilities over time. A benefit of the Machine Learning Algorithm(s) system 97 may have the ability to make the AI Drone(s) 88 more effective in identifying anomalies or potential hazards in future missions.

Embodiments of the AI Drone(s) 88 may further be comprised of an Onboard Processor 25. The Onboard Processor 25 may be any device that serves as the central processing unit, managing and coordinating all operations during flight. The Onboard Processor 25 may have the ability to analyze sensor data and make immediate decisions regarding flight control, navigation, and anomaly detection. A benefit of the Onboard Processor 25 may be that it may allow the AI Drone(s) 88 to operate autonomously, reducing the need for constant remote control and enabling quicker responses to environmental changes during flight.

Embodiments of the AI Drone(s) 88 may further be comprised of an Emergency Landing System 49. The Emergency Landing System 49 may be any system designed to ensure the safe descent and landing of the AI Drone(s) 88 in the event of a malfunction or power failure. The Emergency Landing System 49 may have the ability to guide the AI Drone(s) 88 to perform controlled landings in emergency situations. It may automatically assess the best available landing site based on the drone's location and the surrounding environment. A benefit of the Emergency Landing System 49 may be that it may allow the AI Drone(s) 88 to minimize damage by guiding it to a safe landing zone during emergencies, preserving its hardware and data.

Embodiments of the AI Drone(s) 88 may further be comprised of a Wireless Receiver 19. Wireless Receiver 19 may have the ability to receive wireless signals, such as Wi-Fi, from the Wireless Transmitter 18 which may be located at the Wireless Charging Tower 77. The Wireless Receiver 19 may have the ability to pick up signals from the Wireless Transmitter 18 over long distances.

Embodiments of the AI Drone(s) 88 may further be comprised of a 5G LTE Module 46. The 5G LTE Module 46 may help with highspeed data transfer, allowing the AI Drone(s) 88 to send live video, sensor data, and location updates back to a control center. Its compact design may fit neatly into the drone without adding much weight or bulk. The 5G LTE Module 46 may work over long distances, helping the AI Drone(s) 88 stay connected even when covering large areas. The 5G LTE Module 46 may also function similarly to the Wireless Transmitter 18, possibly working alongside it to maintain communication between the drone and the control system. Both components may serve similar roles, but the 5G LTE Module 46 may focus on providing fast, reliable connections in remote locations. Additionally, the module may allow for software updates to be sent to the AI Drone(s) 88, keeping them up to date without needing manual intervention.

Embodiments of the AI Drone(s) 88 may further be comprised of an Autonomous Navigation System 45. The Autonomous Navigation System 45 may be any system that may have the capability of allowing the AI Drone(s) 88 to independently manage its flight paths, avoid obstacles, and achieve mission objectives without human intervention. The Autonomous Navigation System 45 may have the ability to calculate optimal routes and adjust during flight. A benefit of the Autonomous Navigation System 45 may be that it may have the ability to allow the AI Drone(s) 88 to operate autonomously, efficiently responding to changes in terrain, obstacles, or weather conditions.

Embodiments of the AI Drone(s) 88 may further be comprised of a Power Monitoring System 84. The Power Monitoring System 84 may track the AI Drone(s) 88's battery/power level and may be viewed by a user/control center 31 via a mobile phone, app, device, etc. Wen the battery levels drop below a certain threshold, the Power Monitoring System 84 may alert/notify a/the user/control center 31 and send the AI Drone(s) 88 or the ai drone(s) 88 may automatically return to the nearest Wireless charging tower 77 to recharge.

Embodiments of the AI Drone(s) 88 may further be comprised of an Altimeter 41. The Altimeter 41 may be any device, sensor, or anything that may have the ability to measure the AI Drone(s) 88's altitude by detecting changes in air pressure, allowing the drone to determine its exact height above the ground or obstacles.

Embodiments of the AI Drone(s) 88 may further be comprised of a GPS Module System 17. The GPS Module System 17 may be any system and/or device, sensor and/or anything that may provide the location of the AI Drone(s) 88. The GPS Module System 17 may allow the AI Drone(s) 88 to follow set routes, stay on course, and return to the Wireless charging tower 77 for recharging. It may also help in managing multiple AI Drone(s) 88 by keeping track of their positions and adjusting their flight paths as needed.

Embodiments of the AI Drone(s) 88 may further be comprised of a High Resolution Camera 16. The High Resolution Camera 16 may be any camera capable of providing a 360 degree visual perspective and quality video capture. The High Resolution Camera 16 may allow the AI Drone(s) 88 to capture detailed visual data, giving operators a clear view of the environment. This may be especially useful for missions that require close observation or manual operation. A benefit of the High Resolution Camera 16 is that when the user or control center 31 switches to manual control, they may use the High Resolution Camera 16 to view the drone's surroundings. The High Resolution Camera 16 may provide a live feed that may be streamed directly to a control center, mobile device, or computer. This may allow users to seamlessly transition between automated monitoring and manual operation, giving them the ability to focus on specific areas as needed. The clear, definition footage may help users make informed decisions quickly, whether the AI Drone(s) 88 is performing routine surveillance or responding to a critical situation.

Embodiments of the AI Drone(s) 88 may further be comprised of Sensor(s) 15. Sensor(s) 15 may include various and/or different kinds and/or types of sensor(s), each focused on specific tasks such as detecting heat anomalies and/or infrared activity. The sensor(s) 15 may be able to provide the AI Drone(s) 88, but not limited to detect sparks or heat anomalies from power lines and other potential hazards, using thermal imaging and/or infrared red technology. For example, infrared sensors may assist in identifying activity even in low visibility situations, such as at night or in foggy conditions. The Sensor(s) 15 may work together and may allow the AI Drone(s) 88 to have the ability to gather reliable data, avoid collision, detect heat signatures and/or anomalies.

Embodiments of the AI Drone(s) 88 may further be comprised of a Thermal Imaging Sensor 15a. The Thermal Imaging Sensor 15a may detect and map temperature variations by capturing infrared radiation emitted by objects. Thermal Imaging Sensor 15a may be used to identify hotspots, such as fires, sparks, overheating powerlines, and/or already developing fires. By visualizing heat distribution across large areas, Thermal Imaging Sensor 15a may help the AI Drone(s) 88 detect heat anomalies that are not visible to the naked eye. Thermal Imaging Sensor 15a may function effectively in various conditions, allowing the AI Drone(s) 88 to monitor infrastructure and assess hazardous areas both during the day and at night.

Embodiments of the AI Drone(s) 88 may further be comprised of Infrared (IR) Sensor(s) 15b. The Infrared (IR) Sensor(s) 15b may detect heat variations and movement, allowing the AI Drone(s) 88 to identify potential hazards or monitor activity in lowlight conditions. A benefit of the Infrared (IR) Sensor(s) 15b may be that they may have the ability to enhance the AI Drone(s) 88's effectiveness in security and monitoring operations, especially in low visibility environments.

Embodiments of the AI Drone(s) 88 may further be comprised of LIDAR (Light Detection and Ranging) Sensor(s) 15c. The LIDAR Sensor(s) 15c may use laser light to measure distances and map the surrounding environment in high detail. The LIDAR Sensor(s) 15c may have the ability to help the AI Drone(s) 88 create accurate 3D models of terrain and navigate complex environments. A benefit of the LIDAR Sensor(s) 15c may be that they may have the ability to enhance the drone's navigation and obstacle avoidance capabilities during autonomous operations.

Embodiments of the AI Drone(s) 88 may further be comprised of Malfunction Detection Sensor(s) 15d. The Malfunction Detection Sensor(s) 15d may monitor the internal systems of the AI Drone(s) 88 for potential malfunctions or system failures. The Malfunction Detection Sensor(s) 15d may have the ability to help the AI Drone(s) 88 alert the control center if critical components show signs of failure. A benefit of the Malfunction Detection Sensor(s) 15d may be that they may have the ability to ensure timely maintenance, preventing operational downtime.

Embodiments of the AI Drone(s) 88 may further be comprised of Smoke Detection Sensor(s) 15f. The Smoke Detection Sensor(s) 15f may detect the presence of smoke in the environment, allowing the AI Drone(s) 88 to identify potential fire hazards early. A benefit of the Smoke Detection Sensor(s) 15f may be that they may have the ability to enhance fire prevention efforts by providing early alerts, especially in remote or high risk areas.

Embodiments of the AI Drone(s) 88 may further be comprised of Collision Avoidance Sensor(s) 15e. The Collision Avoidance Sensor(s) 15e may help the AI Drone(s) 88 detect and avoid obstacles during flight. The Collision Avoidance Sensor(s) 15e may have the ability to help the AI Drone(s) 88 adjust its flight path to prevent collisions. A benefit of the Collision Avoidance Sensor(s) 15e may be that they may have the ability to ensure safe navigation, reducing the risk of accidents during autonomous operations.

Embodiments of the AI Drone(s) 88 may further be comprised of Communication Sensor(s) 15g. The Communication Sensor(s) 15g may enable the AI Drone(s) 88 to communicate with the Tower(s) 77 and control centers through internet connectivity. The Communication Sensor(s) 15g may have the ability to help transmit data and ensure seamless communication during missions. A benefit of the Communication Sensor(s) 15g may be that they may have the ability to maintain continuous communication, ensuring effective coordination and data sharing during operations.

Detailed Description of The Embodiments of The Wireless charging tower

Embodiments of the AI Drone and Wireless charging tower System 777 may further comprise Wireless charging tower(s) 77. The Wireless charging tower(s) 77 may vary in height, structure, and design, depending on the specific requirements of the monitoring area. These towers may be constructed from durable materials that allow them to withstand harsh environmental conditions such as extreme winds, intense sunlight, and fluctuating temperatures. The Wireless charging tower(s) 77 may comprise of one or more Solar Panel(s) 110 to generate the energy required for wirelessly recharging the AI Drone(s) 88. The Wireless charging tower(s) 77 may also be comprised of a wireless charging pad 57. The wireless charging pad 57 may wireless charge a ai drone(s) 88 without the need for physical connections, allowing the ai drone(s) to wireless charge while another ai drone(s) 88 takes off. Additionally, the towers may be strategically placed based on the AI Drone(s) 88's flight range to enable efficient recharging during their monitoring cycles. The towers may also communicate with the AI Drone(s) 88 to guide them back to the nearest Wireless charging tower 77 after completing a monitoring cycle.

Embodiments of an AI Drone and Wireless charging tower System 777 may further be comprised of a Wireless charging tower(s) 77. The Wireless charging tower 77 may be comprised of a head 100, a body 200, a base 300, a solar panel(s) 110, and a wireless charging pad 57. The main purpose of the Wireless charging tower 77 is to serve as a wireless charging station for the AI Drone(s) 88.

Embodiments of the Wireless charging tower 77 may further be comprised of a Head 100. The head 100 may be located at the top section of tower 77. The reason the head 100 is may be positioned at the top of the tower(s) 77 is that the height of the tower 77 may provide better placement for components such as the Solar Panel(s) 110, sensors 15, and the Wireless Transmitter 18, among other components. For example, the height may allow the Solar Panel(s) 110 to receive more sunlight, the higher position of the Solar Panel(s) 110 may also improve its ability to convert sunlight efficiently, while the Wireless Transmitter 18 may offer a better internet connection to the AI Drone(s) 88. They head 100 may be comprised with similar sensor(s) 15 that a ai drone(s) 88 have.

Embodiments of the Head 100 may further be comprised of a Wireless Transmitter 18. Placing the Wireless Transmitter 18 within the Head 100 may provide optimal Wi-Fi communication between the AI Drone(s) 88, the system 777.

Embodiments of the Head 100 may further be comprised of a Solar Panel 110. The head may use one or more solar panel(s) 110. The solar panel(s) 110 may be any kind, type, size, device, system that may have the ability of converting sunlight into electricity. The Solar Panel 110 may be responsible of powering the entire system 777. A benefit of the Solar Panel 110 is that it may be able to keep the system 777 running even in remote areas without relying on external power sources.

Embodiments of the Head 100 may further be comprised of a High Resolution Camera 16. The High Resolution Camera 16 may be any type of camera that may have the ability to capture detailed images or videos. The High Resolution Camera 16 may help the system monitor large areas for any changes or issues. A benefit of the High Resolution Camera 16 may be that it provides clear visual data for monitoring.

Embodiments of the Body 200 may further be comprised of a Wireless Charging Pad 57. The Wireless Charging Pad 57 may be any type of pad that may have the ability to charge the AI Drone(s) 88 without needing physical contact. The Wireless Charging Pad 57 may help the AI Drone(s) 88 stay powered and ready for use. A benefit of the Wireless Charging Pad 57 may be that it allows the AI Drone(s) 88 to charge automatically, reducing downtime.

Embodiments of the Body 200 may further be comprised of an Automated Shutter 3. The Automated Shutter 3 may be any type of door that may have the ability to open and close automatically. The Automated Shutter 3 may help protect the AI Drone(s) 88 and the system 777 from outside elements.

Embodiments of the Body 200 may further be comprised of an Electromagnetic Induction 53. The Electromagnetic Induction 53 may be any type of system that may have the ability to create electrical power. The Electromagnetic Induction 53 may help transfer energy to the AI Drone(s) 88 during charging. A benefit of the Electromagnetic Induction 53 may be that it allows for contactless power transfer, increasing the durability of the system.

Embodiments of the Base 300 may further be comprised of a Power Storage System 70. The Power Storage System 70 may be any type of system that may have the ability to store extra power. The Power Storage System 70 may help keep the Wireless charging tower 77 operational even when solar power is low. A benefit of the Power Storage System 70 may be that it ensures consistent power availability.

Embodiments of the Base 300 may further be comprised of a Cooling System 50. The Cooling System 50 may be a device, a method, a system and/or anything that may have the ability to keep the interior components of the wireless charging tower(s) 77 cool. The cooling system 50 may be one or a combination of methods and systems that may have the ability to keep the internal components in operation condition. Under direct sunlight, the cooling system may have the ability to prevent the internal temperature from rising excessively.

1. A device for detecting heat anomalies via the use of an autonomous artificial intelligence drone aerial system,
wherein the autonomous artificial intelligence drone aerial system comprises:
autonomous artificial intelligence aerial drones,
sensors that detect heat anomalies,
sensors that detect electrical faults, and
sensors that detect physical threats.

2. The device of claim 1, wherein:
the artificial intelligence drone are wirelessly charged via a wireless charging pad located within a wireless charging tower.

3. The device of claim 2, wherein:
the wireless charging pad is powered by a solar panel.

4. The device of claim 2, wherein:
the wireless charging pad is powered by a direct connection to a powerline.

5. The device of claim 1, wherein the wireless charging tower further comprises:
automated shutters,
a charging apparatus,
data collection modules, and
a docking apparatus.

6. A method for detecting anomalies via the use of an autonomous artificial intelligence drone aerial system comprising:
an initial deployment phase for autonomous artificial intelligence aerial drones between wireless charging towers,
a decision-making process for the autonomous artificial intelligence aerial drones
a one-way cycle path between wireless charging towers, and
interactions between the autonomous artificial intelligence aerial drones, the wireless charging towers and a central control unit.

7. The method of claim 6 wherein the decision-making process comprises:
analysis of anomalies, wherein the anomalies comprise:
damaged power lines, and
damaged access points.

8. The method of claim 6 wherein the one-way cycle path comprises:
recharging points, and:
monitoring zones.

9. The method of claim 6 wherein the anomaly is a heat anomaly.

10. The method of claim 6 wherein the anomaly is related to a prison.

11. The method of claim 6 wherein the anomaly is related to a military base.

12. The method of claim 6 wherein data collected by the autonomous artificial intelligence aerial drones is stored in a cloud based system.

13. The method of claim 6 wherein data from multiple autonomous artificial intelligence aerial drones and wireless charging towers is collected, analyzed, and shared.

14. A system for detecting anomalies via the use of an autonomous artificial intelligence aerial drones,
wherein the system comprises:
autonomous artificial intelligence aerial drones,
wireless charging tower, comprising:
a wireless charging pad,
sensors that detect heat anomalies,
sensors that detect electrical faults, and
sensors that detect physical threats.

15. The system of claim 14 wherein
the autonomous artificial intelligence aerial drones are programmed to continuously and autonomously monitor an area around a wireless charging tower.

16. The system of claim 14 wherein
the autonomous artificial intelligence aerial drones are programmed to travel between wireless charging towers to cover larger areas.

17. The system of claim 14 wherein
the autonomous artificial intelligence aerial drones:
monitor an area,
gather data,
detect anomalies across the area.

18. The system of claim 17 wherein
after a monitoring cycle is complete the autonomous artificial intelligence aerial drones return to a wireless charging tower,
the autonomous artificial intelligence aerial drones are wirelessly charged by a wireless charging pad, and
the autonomous artificial intelligence aerial drones upload data to a central control unit.

19. The system of claim 17 wherein power is generated for the system via solar panels.

20. The system of claim 17 wherein excess power is stored in a power storage system.
